(19) United States
(12) Patent Application Publication
(10) Pub. No.: US 2026/0327850 A1
(43) Pub. Date: Oct. 22, 2026

(54) POLISHED DIAMOND AND METHOD OF FORMING A DIAMOND WITH A DRY ETCH POLISHED SURFACE

(71) Applicant: Advanced Diamond Holdings, LLC, Beltsville, MD (US)

(72) Inventors: John P. Ciraldo, Clarksburg, MD (US); Joshua Blackketter, Laurel, MD (US); Joseph P. Senderling, Chicago, IL (US)

(21) Appl. No.: 19/180,883

(22) Filed: Apr. 16, 2025

(51) Int. Cl. C30B 25/20; C30B 25/18; C30B 29/04; C30B 33/12

(52) U.S. Cl. CPC C30B 25/20; C30B 25/186; C30B 29/04; C30B 33/12

(57) ABSTRACT

A method of forming a lab grown diamond polishes the “major surface” of a provided diamond wafer using a dry etching process, and then applies a diamond layer to the major surface. The diamond layer includes a C12 isotope, which is helpful in a number of applications, including quantum applications. The method then polishes the diamond layer with a dry etching process to form a diamond wafer with minimal/no lattice defects.

### GOVERNMENT RIGHTS

None

### FIELD

Illustrative embodiments of the invention generally relate to lab grown diamonds and, more particularly, various embodiments of the invention relate to polished lab grown diamonds.

### BACKGROUND

Polishing diamond wafers is an important step in refining lab-grown diamonds for industrial and electronic applications. The process typically begins with mechanical polishing, where the rough wafer surface is smoothed using diamond grit abrasives. Since diamond is the hardest known material, only finer diamond particles can effectively grind and polish its surface. This typically is done using a lapping machine equipped with a rotating metal plate coated with diamond slurry. The wafer is pressed against the plate under controlled pressure, gradually reducing surface roughness and achieving a uniform finish.

After mechanical polishing, a chemical-mechanical polishing (CMP) step typically is employed to further enhance the wafer's surface quality. In this process, a reactive chemical agent is used along with nano-sized diamond abrasives to achieve a finer smoothness. CMP minimizes subsurface damage, removes micro-defects, and improves transparency.

Unfortunately, these processes often damage or otherwise change the crystal lattice of the diamond. Among other issues, damaging the diamond lattice disrupts its crystalline structure, leading to several issues depending on the application. In optics and laser technologies, lattice defects introduce scattering centers, reducing transparency, and degrading light transmission. For semiconductors and quantum computing, defects create unwanted energy states and charge traps, negatively impacting the performance of diamond-based transistors, NV (nitrogen-vacancy) centers, and sensors.

Mechanically, damage weakens the diamond's structural integrity, making it more prone to fracture, which is problematic for cutting tools, high-pressure anvils, and industrial applications. Additionally, thermal conductivity—one of diamond's valuable properties—can be compromised, reducing its effectiveness in heat dissipation for high-power electronics.

### SUMMARY OF VARIOUS EMBODIMENTS

In accordance with one embodiment, a method of forming a lab grown diamond polishes the “major surface” of a provided diamond wafer using a dry etching process, and then applies a diamond layer to the major surface. The diamond layer includes a C12 isotope, which is helpful in a number of applications, including quantum applications. The method then polishes the diamond layer with a dry etching process to form a diamond wafer with minimal/no lattice defects.

The diamond layer may be applied to the major surface in a nitrogen environment of an N15 isotope. Preferably, the diamond layer is polished with a plasma process (e.g., a reactive ion etching process). Moreover, to provide the diamond wafer, the method may form the diamond wafer using a CVD process in a chamber substantially free of nitrogen. The process also may irradiate the diamond wafer to form a plurality of nitrogen vacancy centers in the diamond layer.

To further process the diamond wafer, the method may etch the diamond layer. When used for certain applications, the diamond wafer may have a thickness of between 100 nanometers and 5 microns, including both endpoints.

In accordance with another embodiment, a method of forming a lab grown diamond may use a CVD process to grow a diamond wafer in an environment having an N15 isotope. Next, the method may polish a surface of the diamond wafer using a dry etching process, and then heat and irradiate the diamond wafer to form a plurality of nitrogen vacancy centers in the diamond wafer.

In accordance with still other embodiments, a diamond wafer has a diamond structure having both a C12 isotope and an N15 isotope. Importantly, the wafer has an upper surface dry polished with no lattice damage. The diamond structure is configured to form a plurality of nitrogen vacancy centers after application of sufficient heat or irradiation.

In accordance with yet other embodiments, a diamond wafer has a diamond structure having both a C12 isotope and an N15 isotope. Importantly, the wafer has an upper surface dry polished with no lattice damage. The diamond structure has a plurality of nitrogen vacancy centers.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a perspective view of a lab-grown diamond wafer produced in accordance with various embodiments.

FIG. 2 schematically illustrates a cross-sectional view of a lab grown diamond wafer according to one embodiment, taken along line A-A of FIG. 1

FIG. 3 shows a process of forming the diamond wafer of FIGS. 1 and 2 in accordance with illustrative embodiments.

FIG. 4A schematically shows a cross-sectional view of the diamond wafer at step 300 of the process of FIG. 3.

FIG. 4B schematically shows a cross-sectional view of the diamond wafer at step 302 of the process of FIG. 3.

FIG. 4C schematically shows a cross-sectional view of the diamond wafer at step 304 of the process of FIG. 3.

FIG. 4D schematically shows a cross-sectional view of the diamond wafer at step 306 of the process of FIG. 3.

FIG. 5 schematically shows another cross-sectional view of the diamond wafer of FIG. 1 across line A-A in accordance with another embodiment.

FIG. 6 shows a process of forming the diamond wafer of FIGS. 1 and 5 in accordance with illustrative embodiments.

FIG. 7A schematically shows a cross-sectional view of the diamond wafer at step 600 of the process of FIG. 6.

FIG. 7B schematically shows a cross-sectional view of the diamond wafer at step 602 of the process of FIG. 6.

### DESCRIPTION OF ILLUSTRATIVE EMBODIMENTS

Illustrative embodiments form diamond wafers with NV centers using a dry etching polishing process. To that end, a diamond fabrication method may use a chemical vapor deposition technology to form a diamond wafer with a surface in need of polishing. To avoid damaging the wafer, the method polishes that surface with a dry etching process (e.g., a plasma process). In some embodiments, some or all the wafer is grown from a C12 carbon isotope in a N15 nitrogen isotope environment to ultimately form NV centers after heating and irradiation. The resulting wafers preferably are configured for quantum applications. Details of illustrative embodiments are discussed below.

In the context of this patent application, while NV centers are discussed, alternative embodiments may apply to other centers, generically referred to as “XV” centers, where X represents the relevant atom and V denotes the vacancy. In these embodiments, the diamond may be formed or doped with various atoms, such as tin, nickel, silicon, or other known atoms. These atoms, also referred to as “impurities,” can be used for X, with electrons tending to be trapped in the XV center, thereby forming the quantum center. The nature of the color center varies with different impurities, which can offer specific advantages in quantum applications. Some embodiments can use mixed isotopes (e.g., N14 isotope with another atom)

The use of nitrogen to form NV centers is discussed in greater detail below. However, it is important to note that some embodiments extend beyond the use of nitrogen. The inclusion of different impurities alters the characteristics of the color center, potentially enhancing performance in certain quantum applications. This flexibility allows for the optimization of the quantum center properties based on the specific requirements of the application.

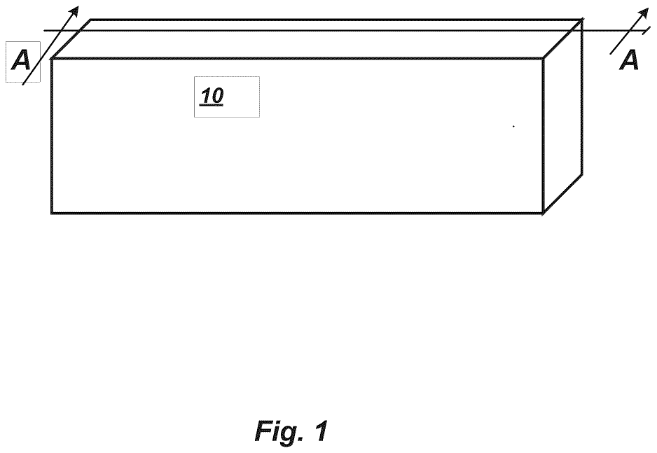

FIG. 1 schematically shows a perspective view of a lab-grown diamond wafer 10 produced in accordance with various embodiments. As shown, the diamond wafer 10 has a generally cuboid body with a top/major face and a bottom/major face (from the perspective of the drawings). The top/major face and the bottom/major face each has a much larger surface area than that of the side surfaces of the wafer. For quantum applications, such as quantum computing, the wafer 10 preferably has a plurality of nitrogen vacancy centers (“NV centers”).

As discussed in greater detail below, the diamond wafer 10 is formed using a chemical vapor deposition (CVD) process, such as microwave plasma-assisted CVD, in which a carbon-rich gas mixture is activated into a plasma phase and used to grow single-crystal diamond on a diamond substrate. The cuboid shape depicted in the drawing is a simplified geometric representation of the wafer 10. Other embodiments may be sized and shaped differently from that shown. The growth process allows precise control over layer thickness, dopant concentration, and crystal orientation, which is important for the creation of quantum-grade diamond material.

Embedded within the CVD-grown diamond are the noted NV centers, which, as known by those in the art, are specific point defects in the diamond lattice of a substitutional nitrogen atom adjacent to a missing carbon atom (vacancy). These NV centers can exist in different charge states, with the negatively charged NV⁻ state being of particular interest for quantum applications due to its optically addressable spin properties. The NV⁻ center has a spin-triplet ground state (S=1) that can be initialized, manipulated, and read out using a combination of microwave and optical excitation, even at room temperature.

NV centers can act as stable quantum bits (qubits) or nanoscale magnetic field sensors. Their spin-dependent photoluminescence enables optical readout of quantum states, making them highly attractive for applications such as quantum computing, quantum repeaters, magnetometry, and electrometry. When used for sensing, NV centers can detect minute variations in magnetic fields, electric fields, strain, or temperature, down to nanoscale spatial resolution. This makes them ideal for use in biological imaging, scanning probe microscopy, and quantum-enhanced measurement systems.

In illustrative embodiments, the NV centers may be distributed either uniformly throughout the grown diamond layer, or confined to a defined region near the upper surface—referred to as a sensing layer. The creation of these centers can be achieved either in situ during CVD growth by introducing nitrogen gas into the growth reactor, or post-growth by ion implantation of nitrogen followed by thermal annealing to mobilize vacancies and promote NV center formation. The specific depth, density, and alignment of NV centers can be engineered depending on the intended quantum application.

While FIG. 1 simplifies the wafer's geometry, various embodiments may incorporate additional structures, such as microwave antennas, waveguides, photonic cavities, or surface electrodes, to enable precise control and readout of the NV centers. Nonetheless, the cuboid form of the wafer 10 offers a convenient and scalable platform for quantum device fabrication, allowing consistent growth, processing, and integration across multiple devices.

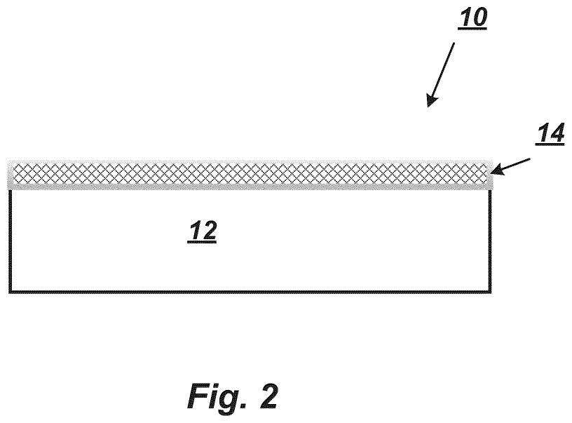

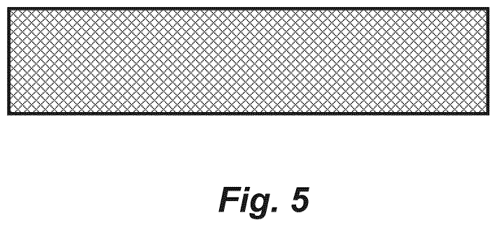

Two figures show cross-sectional views of two different embodiments across line A-A of FIG. 1. The first, FIG. 2, schematically illustrates a cross-sectional view of a lab grown diamond wafer 10 according to one embodiment, taken along line A-A of FIG. 1. This embodiment of the wafer 10 includes a pure diamond base wafer 12 without NV centers, and an upper layer 14 that incorporates NV centers. In FIG. 2 (and FIG. 5, discussed below), NV centers within diamond material are depicted with hatching.

The base wafer 12 includes a single-crystal diamond grown by CVD to be substantially free of impurities and lattice defects. In certain embodiments, the base wafer 12 is a high-purity Type IIa CVD diamond, containing less than 1 part per billion nitrogen and minimal concentrations of boron or other contaminants. This base wafer 12 thus provides a robust, optically transparent, and low-defect substrate for hosting quantum-grade diamond structures.

The thin epitaxial diamond layer 14 (referred to as “upper layer 14” above) formed directly on the top surface of the base wafer 12 includes the NV centers. This layer 14 contains a controlled concentration of NV centers—point defects formed by a substitutional nitrogen atom adjacent to a lattice vacancy. This epitaxial layer 14 may have a thickness ranging from approximately 100 nanometers to several micrometers (e.g., 5 micrometers). In one embodiment and as discussed below, this upper layer 14 may be deposited by CVD in the presence of N15 nitrogen-containing precursor gases. After deposition, the wafer 10 may be irradiated to introduce vacancies, followed by an annealing process to form NV centers with precise or otherwise desired spatial distribution and density. The resulting upper layer 14 is typically formed from isotopically enriched in C12 to enhance spin coherence properties.

The interface 16 between the pure diamond base wafer 12 and the NV-containing layer 14 is epitaxial, maintaining the single-crystal continuity throughout the wafer 10. Because both layers 12 and 14 are diamond, share compatible lattice structures, and are formed as noted below, the wafer 10 is a monolithic, defect-minimized structure configured for quantum, photonic, or sensing applications.

Alternatively, the base wafer 12 may be a natural single-crystal diamond, such as a Type IIa diamond with very low native nitrogen content. In such embodiments, the NV-containing upper layer 14 may still be grown by CVD and engineered as described above. The use of a natural diamond base can offer certain advantages in terms of crystalline perfection or availability of large substrates, although CVD-grown bases may offer tighter control over impurity levels and isotopic composition.

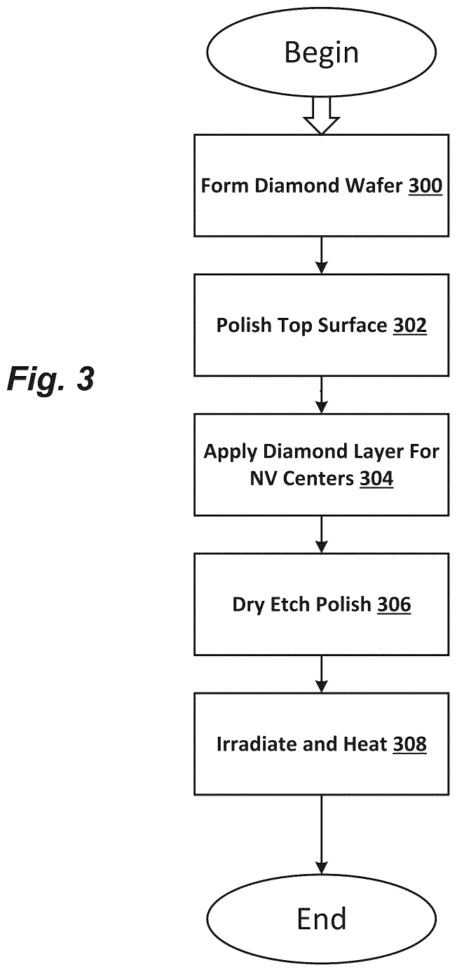

FIG. 3 shows a process of forming the diamond wafer 10 of FIGS. 1 and 2 in accordance with illustrative embodiments. It should be noted that this process is substantially simplified from a longer process that normally would be used to form the lab-grown diamond wafer 10. Accordingly, the process may have additional steps that those skilled in the art likely would use. In addition, some of the steps may be performed in a different order than that shown, or at the same time. Those skilled in the art therefore can modify the process as appropriate. Moreover, as noted above and below, materials and structures noted may be but one of a wide variety of different materials and structures that may be used. Those skilled in the art can select the appropriate materials and structures depending upon the application and/or other constraints. Accordingly, discussion of specific materials and structures is not intended to limit all embodiments. It also should be noted that the wafer 10 of step 300 below may be formed by being cut from a larger wafer, or formed as a stand-alone wafer 10 without the necessity of being cut from larger/thicker wafer.

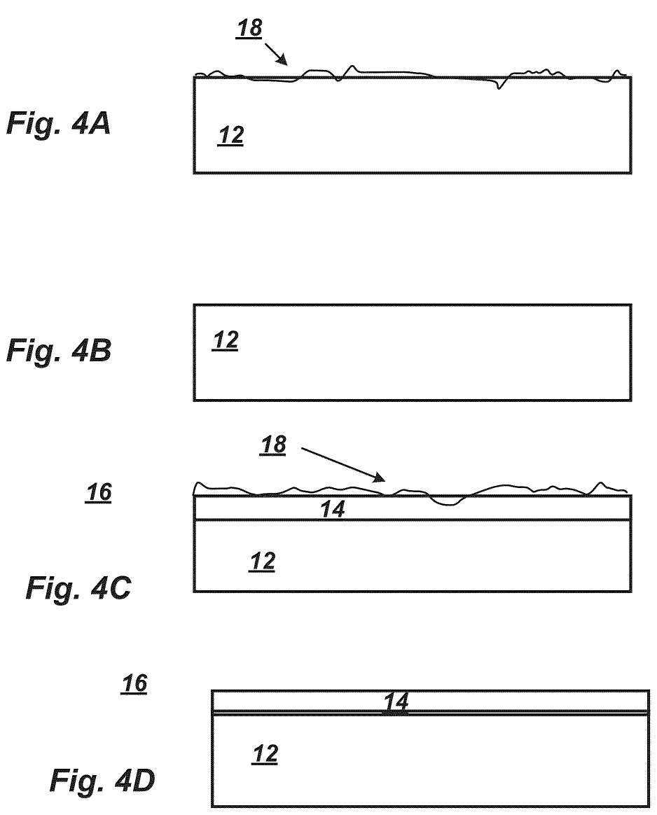

The process begins at step 300, which forms a substantially pure diamond wafer, such as the wafer 10 of FIGS. 1 and 2. FIG. 4A schematically shows a cross-sectional view of the diamond wafer 10 at this stage. Specifically, as known by those in the art, processes form a lab-grown diamond crystal by generally replicating the natural diamond growth conditions using advanced technological methods. Two primary methods for growing diamond crystals are known as High-Pressure High-Temperature (HPHT) and Chemical Vapor Deposition (CVD). Illustrative embodiments use the CVD method, while alternative embodiments use the HPHT method. Both processes start with a diamond seed, which is a tiny piece of pure diamond that serves as a template for crystal growth.

With the HPHT method, the diamond seed is placed in a press that simulates the extreme conditions of the Earth's mantle—pressures of 5-6 GPa (gigapascals) and temperatures exceeding 1,500 °C (2,732 °F). A carbon source, such as graphite or a metal-carbon solution, is introduced, and under these conditions, the carbon atoms dissolve and re-crystallize onto the diamond seed. Over several days to weeks, the diamond grows layer by layer, forming a larger single-crystal diamond. HPHT is widely used to create high-quality diamonds for industrial applications and gem-quality stones.

The CVD method, in contrast, grows diamonds in a low-pressure environment using a plasma reactor. As a pure diamond, this and other methods preferably grow the wafer 10 in a chamber with a substantially nitrogen-free environment. A hydrocarbon gas (e.g., methane, CH₄) is introduced into the reactor chamber along with hydrogen (H₂). When subjected to microwave or radio-frequency plasma, the gas ionizes, breaking down the methane and releasing carbon atoms. These carbon atoms settle onto the diamond seed, gradually building up the crystal layer by layer. CVD allows for greater control over the diamond's purity and size, making it a preferred method for electronics, quantum devices, and high-purity optical applications.

Either method produces a diamond wafer 10 having rough surfaces 18. FIG. 4A schematically shows one example of that rough surface 18. For simplicity, all rough surfaces in the figures are identified by reference number “18.” Among those surfaces may be the surfaces with the largest surface areas (i.e., the “major” surface(s)). Regardless of whether the base wafer 12 is formed using CVD or HPHT, or derived from a natural diamond crystal, the resulting base wafer 12 typically exhibits an undesirably high surface roughness upon formation. This roughness is often present on the wafer's major surfaces—the broad, flat surfaces that define the top and bottom faces of the wafer 12 and comprise the largest surface areas—as well as on edge or peripheral surfaces. Such surface irregularities are generally undesirable for many downstream applications, particularly those involving quantum devices, photonic structures, or epitaxial overgrowth, where optical clarity, uniformity, and interface quality are important.

Surface roughness may arise in several ways. In CVD-grown diamond, for example, step bunching, non-uniform nucleation, and anisotropic growth rates across different crystal facets can lead to microscopic or nanoscopic surface features such as terraces, pits, or ridges. Similarly, when using a natural diamond base, mechanical slicing and lapping introduce sub-surface damage and uneven topographies. Subsequent processes such as irradiation, annealing, or chemical treatments may further accentuate surface features. In either case, standard as-grown or as-cut diamond surfaces are generally not suitable for high-precision applications without further planarization or polishing.

This roughness can interfere with a wide range of critical functions. For instance, in quantum sensing or communication applications, uneven surfaces may scatter light or cause wavefront distortion, degrading optical readout fidelity. In layered structures or bonded assemblies, non-uniform surfaces may inhibit strong, uniform bonding, or lead to interfacial defects. Moreover, attempts to deposit or grow additional layers—such as doped diamond, epitaxial layers, or dielectric coatings—on rough surfaces may result in non-uniform thickness, poor adhesion, or stress concentrations. As such, achieving atomically flat, defect-minimized surfaces through additional polishing or surface treatment steps is often important to enable high-performance diamond-based devices.

Some prior art methods can introduce micro-cracks, dislocations, strain, and other lattice defects into the crystal lattice of wafer 10, especially near the surface. These defects undesirably distort the atomic arrangement, potentially degrading the wafer's optical, electronic, or mechanical properties. In precision applications, such damage can compromise device performance or yield.

The inventors recognized this problem. Accordingly, illustrative embodiments use a much less damaging polishing technique. Specifically, illustrative embodiments dry etch the base wafer 12 to reduce or eliminate the surface roughness present on at least one major surface of the base wafer 12—typically the surface intended for subsequent processing or device fabrication. As shown, this rough surface 18, referred to herein as the “upper surface,” may exhibit nanoscale or microscale

More specifically, to polish, illustrative embodiments perform a dry etch process at step 302, in which the rough upper surface is exposed to a plasma-based etching environment, such as inductively coupled plasma reactive ion etching (ICP-RIE). In one example, an oxygen-containing plasma isotropically or anisotropically etches the surface asperities in a controlled manner. The etch chemistry and process parameters—such as RF power, chamber pressure, gas flow rates, and etch duration—are optimized to remove only a targeted thickness of diamond material (e.g., tens to hundreds of nanometers) without introducing subsurface damage, crystal disorder, or unwanted etch pits. As such, the surface may be free of lattice defects (i.e., no defects) produced by the polishing process.

This non-contact, lattice-preserving etch process enables the formation of a smooth, planar surface suitable for high-precision applications. The resulting surface may exhibit significantly reduced root-mean-square (RMS) roughness, often on the order of sub-nanometer levels, depending on the etch duration and conditions. For example, the process may achieve RMS surface roughness values in the range of about 0.3 to 2 nanometers. An RMS roughness below about 1 nm is typically desirable for coherent optical coupling and near-surface NV center stability, while roughness below about 0.5 nm may be required for certain photonic cavity or waveguide structures. Post-etch metrology—such as atomic force microscopy (AFM), scanning electron microscopy (SEM), or Raman spectroscopy—can be used to confirm both the smoothness and crystalline integrity of the etched surface. This surface conditioning step produces no or negligible crystal lattice damage, enabling high-yield fabrication of quantum devices, photonic circuits, or epitaxial overgrowth structures on the base wafer 12.

Next, after dry polishing the pure diamond base wafer 12 to reduce surface roughness, step 304 deposits the epitaxial upper layer 14 on the polished upper surface using CVD. This layer 14 does not yet contain NV centers, but is configured to form them later through irradiation and annealing. It includes nitrogen atoms placed within a carefully controlled region of the diamond lattice.

The process preferably uses microwave plasma-assisted CVD (MPACVD), which allows precise control overgrowth conditions and chemical composition. A gas mixture flows into a vacuum chamber, where microwave energy excites it into a plasma. The plasma breaks down methane (CH₄) and hydrogen (H₂), enabling atomic carbon to settle onto the wafer surface and grow new diamond that continues the existing crystal structure.

The carbon source is methane enriched with C 12, often at 99.9% purity or higher, although lower purities may suffice, such as down to 98%. This reduces C13 content, which can interfere with quantum coherence due to its nuclear spin. The nitrogen source N15 may be added in small, controlled amounts using N15₂ or N15-labeled ammonia. Typical concentrations range from 0.1 to 10 parts per million (ppm), enough to seed future NV centers without adding defects or excess charge noise.

CVD growth conditions may be optimized for high-purity, single-crystal diamond deposition. Common conditions include:
Substrate temperature: approximately 800 °C to 1150 °C,
Chamber pressure: approximately 80 to 250 Torr,
Methane concentration: approximately 0.5% to 20% in hydrogen,
Microwave power: between 3 and 15 kW, depending on chamber size,
Nitrogen (e.g., N15) addition: controlled in the ppm range, with Nitrogen or N15 isotopic enrichment above 95%.

To create a nitrogen-doped region within the upper diamond layer 14, the process may add N15 gas during the CVD growth in one of two ways. In some embodiments, the process introduces N15 gas only during part of the growth, forming a thin nitrogen-doped zone within the upper layer 14. For example, if the upper layer 14 is 10 micrometers thick, the process might introduce N15 for only 100 nanometers of growth. This creates a spatially confined band of nitrogen atoms, while the surrounding diamond remains nitrogen-free. The location of this band—near the surface or deeper below—can be precisely controlled by adjusting when the nitrogen flow starts and stops.

In other embodiments, the process adds N15 gas throughout the entire growth of the upper layer 14. This produces a uniformly nitrogen-doped upper layer 14, where substitutional nitrogen atoms are distributed evenly from the interface 16 with the base wafer 12 to the surface. This approach may suit applications where a broad NV-active region is preferred or where vertical precision is less important.

In both cases, the diamond lattice contains only substitutional N15 atoms, and possibly a small number of unintentional vacancies due to thermal effects. Indeed, this diamond lattice may have negligible numbers of or no NV centers yet (not activated yet).

At this stage, the upper layer 14 now has a rough surface 18 that also needs to be polished (e.g., see FIG. 4C, which schematically shows this rough surface 18). Accordingly, step 306 dry etch polishes this upper surface in a manner like that described above regarding step 302. FIG. 4D schematically shows the wafer 10 at this stage of development—with the rough surface 18 now smoothed.

During or after one or more of the growth and polishing steps described above, the outer edge of the diamond wafer 10 may have roughness, irregular contours, or microcracks from cutting or handling. To improve the mechanical stability, reduce chipping, and ensure compatibility with wafer handling tools, laser etching can be used to trim and refine the edge. This involves directing a high-power laser beam—often a pulsed UV or infrared laser—around the perimeter of the wafer 10. The laser locally heats and vaporizes the diamond material or induces controlled microfracturing, allowing for precise edge shaping or beveling.

Laser etching can also be used to deburr or smooth sharp or jagged edges that could cause stress concentrations or interfere with mounting in a device package. In some cases, the laser is used to engrave alignment marks, ID codes, or fiducial references on the wafer's edge. This step is typically done before final polishing or just after, depending on the desired sequence and how much material is removed during polishing.

In quantum applications, clean and stable wafer edges help prevent physical damage during fabrication or measurement and can reduce the risk of particulate contamination, which may otherwise affect NV center readout near the wafer's perimeter.

The wafer 10 is now ready for further processing to form or activate the NV centers. At this point in the process, the diamond contains substitutional N15 atoms within a defined region, but no vacancies. To form the NV centers, the process first generates vacancies in the diamond lattice and then mobilizes those vacancies so they can pair with nitrogen atoms.

Step 308 thus irradiates the wafer 10 with high-energy particles—typically electrons, though ions or neutrons may also be used—to knock carbon atoms out of the lattice and create vacancies. Electron energies often range from 1 to 10 MeV, with doses between 10¹⁶ and 10¹⁸ electrons per square centimeter, depending on the desired NV density. The energy preferably is high enough to displace carbon atoms without damaging the overall crystal structure. This step does not yet create NV centers, but introduces mobile defects that will later pair with nitrogen.

After irradiation, the wafer 10 is heated in a high-temperature anneal, typically between 800 °C and 1000 °C. At these temperatures, the vacancies become mobile and diffuse through the lattice. When a vacancy encounters a substitutional nitrogen atom, it forms a stable NV center. The annealing time and temperature profile can be tuned to control the number and distribution of NV centers, and to repair minor crystal damage introduced by irradiation. Annealing is usually performed in vacuum or forming gas to prevent unwanted surface reactions. Accordingly, this completes the process, producing the wafer 10 of FIG. 2.

By combining spatially controlled nitrogen doping with global irradiation and annealing, the process forms NV centers only in the regions where nitrogen was intentionally introduced. This level of control may be used to form reliable quantum sensors, scalable qubit arrays, and integrated photonic structures. The resulting NV layer may now be characterized for depth, density, and spin coherence properties before further device fabrication.

FIG. 5 schematically shows a cross-sectional view of the diamond wafer 10 of FIG. 1 across line A-A in another, unitary embodiment. Unlike that of FIG. 2, this embodiment does not have an upper layer 14. Instead, this embodiment has NV centers in the initially grown diamond wafer. To distinguish from the wafer 10 of FIG. 2, this embodiment will be referred to as wafer 10A.

Specifically, this embodiment comprises a single-layer diamond wafer 10A, formed from a single-crystal diamond—typically grown by CVD processes—in which NV centers are distributed throughout the full thickness of the wafer 10A. During growth, nitrogen gas (preferably N15) is introduced continuously into the furnace/environment, resulting in uniform doping across the wafer 10A to form NV centers.

In alternative embodiments, the wafer 10A may still include a single diamond layer, but the NV centers may be confined to specific regions within that layer. For example, nitrogen gas may be introduced only during a portion of the CVD growth, creating a vertically confined nitrogen-doped zone. After irradiation and annealing, NV centers form only in that zone, leaving the rest of the wafer 10A free of NV centers. Similarly, spatial control over irradiation (e.g., using a mask or focused beam) can localize vacancy formation, enabling patterned NV regions without changing the nitrogen profile.

This single-layer structure, whether uniformly doped or selectively activated, contrasts with the multilayered embodiment described earlier, where a high-purity base wafer 10A supports a distinct NV-containing upper layer 14. While the layered approach offers tighter control over NV depth and interfaces, the single-layer wafer 10A simplifies fabrication and may offer advantages for bulk sensing, imaging, or applications that benefit from NV centers at multiple depths.

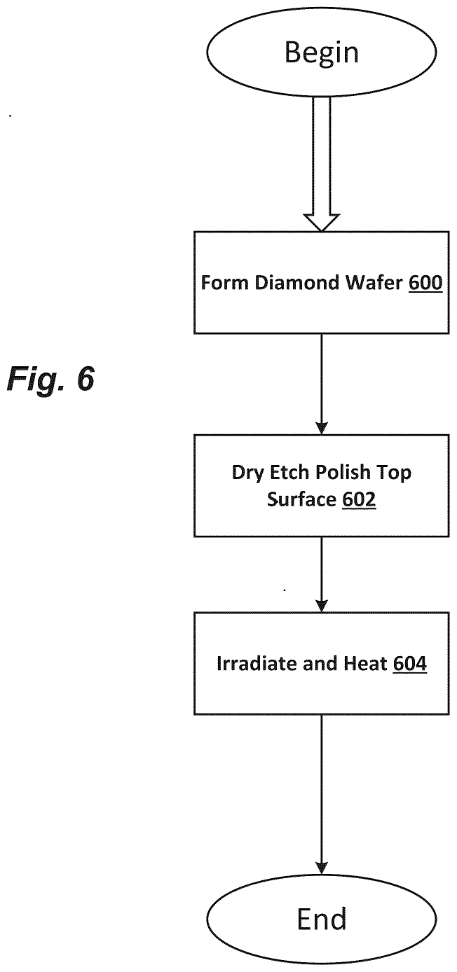

FIG. 6 shows a process of forming the diamond wafer 10A of FIGS. 1 and 5 in accordance with illustrative embodiments. As with the process of FIG. 3, it should be noted that this process is substantially simplified from a longer process that normally would be used to form a lab-grown diamond wafer 10A. Accordingly, the process may have additional steps that those skilled in the art likely would use. In addition, some of the steps may be performed in a different order than that shown, or at the same time. Those skilled in the art therefore can modify the process as appropriate. Moreover, as noted above and below, materials and structures noted may be but one of a wide variety of different materials and structures that may be used. Those skilled in the art can select the appropriate materials and structures depending upon the application and other constraints. Accordingly, discussion of specific materials and structures is not intended to limit all embodiments. It also should be noted that the wafer 10A of step 600 below may be formed without begin cut from a larger wafer, or formed as a stand-alone wafer without the necessity of being cut from larger/thicker wafer.

The process begins at step 600, which forms the diamond wafer 10A. This step may be like that described above regarding step 300, although it has some significant differences. Specifically, to fabricate a single-layer diamond wafer 10A configured to ultimately have NV centers, the process begins with microwave plasma-assisted chemical vapor deposition (MPACVD). This method grows high-purity, single-crystal diamond from gas-phase precursors in a vacuum chamber. As with the embodiments described above, equipment used to produce the wafer 10A includes a microwave plasma reactor, capable of generating a stable plasma at powers typically ranging from 1 to 3 kilowatts. The substrate—either a seed diamond or a previously polished diamond wafer—is placed on a heated stage within the chamber, which maintains a temperature between 800 °C and 1000 °C using a resistive or RF-heated susceptor.

A gas mixture containing hydrogen (H₂) and methane (CH₄) serves as the carbon source. To reduce spin decoherence from nearby nuclear spins, the methane may be isotopically enriched with C12, typically at concentrations discussed above. The hydrogen/methane ratio is tuned to control the growth rate and film quality; methane may be maintained at 0.5% to 2% of the total gas flow. Under these conditions, carbon atoms deposit onto the diamond substrate to grow an epitaxial, single-crystal layer that continues the diamond lattice.

To incorporate nitrogen, as discussed above, N15-enriched gas is added to the gas flow. As in other embodiments, this may be introduced as N15₂ or N15-labeled ammonia (N15H₃). In the uniform doping approach, the N15 gas flows continuously throughout the entire CVD process. This results in a diamond layer uniformly doped with substitutional N15 atoms from surface to substrate interface.

In contrast, a non-uniform doping approach may use a time-based control of the N15 gas during CVD growth. The gas flow starts and stops at precise intervals, often controlled by a mass flow controller (MFC) integrated with the CVD system's software. For example, if the total diamond layer is 10 micrometers thick, N15 may be introduced only during the growth of a 200-nanometer segment, placing nitrogen atoms within a confined layer. Some embodiments may control N15 flow to produce two or more confined nitrogen layers separated by pure diamond layers.

The result is a single-crystal diamond wafer 10A that is configured to form either uniform or spatially defined NV centers, depending on how nitrogen was introduced during growth. The equipment used—microwave plasma reactor, electron accelerator, and high-temperature annealing furnace—provides precise control over crystal quality, impurity profile, and defect engineering. The choice between uniform and localized NV regions depends on the application: uniform doping benefits bulk sensing and imaging, while confined layers offer better performance for quantum photonic and spintronic devices.

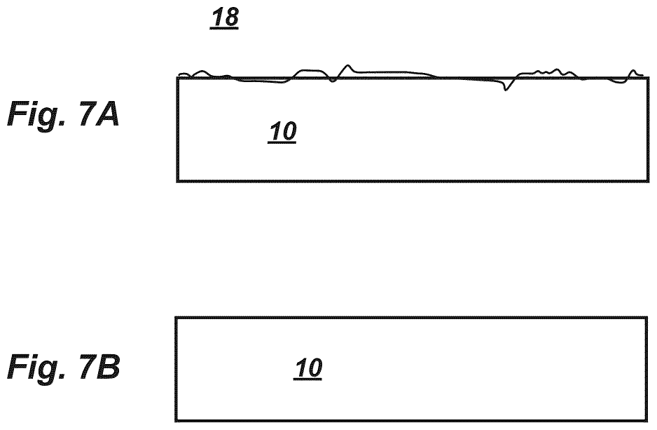

FIG. 7A schematically shows the diamond at the end of this step 600. Specifically, as shown, the wafer 10A comprises a single-crystal diamond layer grown by MPACVD. The diamond is uniformly doped with C12 carbon and N15 nitrogen, either throughout its entire thickness or within a precisely defined sub-layer, depending on how the nitrogen was introduced during growth. The structure remains free of NV centers, as no irradiation or annealing has yet been performed. Instead, the wafer 10A contains substitutional N15 atoms embedded in a high-purity C12 diamond lattice, configured for later NV center formation.

Following growth, in a manner like the embodiment of FIG. 2, the wafer 10A typically exhibits surface roughness (see “18”) caused by step bunching, microfaceting, or other growth-related effects. To prepare the surface for further processing—such as photonic structuring, bonding, or implantation—the wafer 10A undergoes surface polishing. In this embodiment, a non-contact dry etch process, such as inductively coupled plasma reactive ion etching (ICP-RIE) using an oxygen plasma, removes surface asperities while preserving the integrity of the underlying crystal lattice—essentially removing the roughness of the surface shown schematically as 18. This process is like those described above regarding the embodiment of FIG. 2. After polishing, the wafer 10A presents a flat, clean, and defect-minimized surface (e.g., no crystal lattice damage at or near the surface), suitable for high-precision fabrication steps or for storage until later NV activation. FIG. 7B schematically shows a cross-sectional view of the wafer 10A at this stage.

The process concludes at step 604, which irradiates and then heats the wafer 10A to form the NV centers (FIG. 5). Specifically, as described above, the wafer 10A first undergoes irradiation with high-energy particles, most commonly electrons in the energy range of 1 to 10 MeV. This irradiation displaces carbon atoms from the diamond lattice, creating vacancies. The dose is selected based on the desired NV density and typically falls between 10¹⁶ and 10¹⁸ electrons per square centimeter. The process uniformly distributes vacancies throughout the wafer 10A or within a targeted region, depending on the irradiation method and setup.

Following irradiation, the wafer 10A is annealed in a high-temperature furnace, usually under vacuum or in a reducing atmosphere such as forming gas (a mixture of hydrogen and nitrogen). The annealing temperature typically ranges from 800 °C to 1000 °C, with the exact temperature and duration chosen to optimize vacancy mobility and NV center formation while minimizing unwanted defect complexes. During this thermal treatment, the vacancies migrate through the diamond lattice and pair with substitutional N15 atoms, forming stable NV centers.

The result is a single, unitary diamond wafer 10A containing NV centers either throughout its entire volume or within a well-defined, nitrogen-rich region. The NV centers are now optically and magnetically active, and their properties—such as spin coherence, fluorescence, and depth—can be measured and tuned for specific applications. The wafer 10A may now be used directly in sensing or quantum devices or undergo further microfabrication to define photonic structures, electrodes, or protective coatings.

In a manner like the process of FIG. 3, this final step completes the NV center formation process. By controlling each stage—CVD growth, nitrogen doping, vacancy creation, and annealing—the process yields a highly engineered diamond substrate tailored for quantum sensing, imaging, or communication technologies.

Alternative embodiments may polish using mechanical polishing or laser ablation in addition to or instead of dry etching. Those skilled in the art can select the appropriate method based on the application.

Accordingly, plasma-based dry etch processes—such as inductively coupled plasma reactive ion etching (ICP-RIE)—to polish the diamond surface offers several advantages for quantum applications. Unlike mechanical or slurry-based methods, dry etching removes surface roughness without introducing sub-surface damage or strain that could degrade the coherence of near-surface NV centers. The process enables atomic-level smoothing of the diamond surface, often achieving RMS roughness below 0.5 nanometers, while preserving the integrity of the crystal lattice. This level of precision is valuable—and often essential—for industry-standard applications involving surface-coupled NV centers, such as quantum sensing or photonic device integration. In these contexts, stray magnetic or electric fields from surface defects can shorten coherence times or reduce signal fidelity. As a result, wafers 10 polished using dry etch methods often exhibit more stable and reliable performance when implemented in quantum technologies.

The embodiments of the invention described above are intended to be merely exemplary; numerous variations and modifications will be apparent to those skilled in the art. Such variations and modifications are intended to be within the scope of the present invention as defined by any of the appended claims.

What is claimed is:

1. A method of forming a lab grown diamond, the method comprising:
providing a diamond wafer having a major surface;
polishing the major surface using a dry etching process;
applying a diamond layer to the major surface, the diamond layer comprising a C12 isotope; and
polishing the diamond layer with a dry etching process to form a given diamond wafer.

2. The method of claim 1 wherein applying comprises applying the diamond layer to the major surface in a nitrogen environment.

3. The method of claim 2 where the nitrogen comprises an N15 isotope.

4. The method of claim 1 wherein applying comprises applying the diamond layer to the major surface in an environment comprising one or more of nitrogen, tin, nickel, and silicon.

5. The method of claim 4 wherein applying comprises doping with phosphorous, boron, or both phosphorous and boron.

6. The method of claim 1 wherein polishing the diamond layer comprises polishing the diamond layer with a plasma process.

7. The method of claim 1 wherein providing a diamond wafer comprises forming the diamond wafer using a CVD process in a chamber substantially free of nitrogen.

8. The method of claim 1 further comprising irradiating the given diamond wafer to form a plurality of nitrogen vacancy centers in the diamond layer.

9. The method of claim 1 wherein the given diamond wafer is configured for at least one quantum application.

10. The method of claim 1 further comprising laser etching the diamond layer.

11. The method of claim 1 wherein the diamond layer has a thickness between 100 nanometers and 5 microns, including both endpoints.

12. The method of claim 1 polishing comprises using a reactive ion etching process.

13. A lab grown diamond produced by the method of claim 1.

14. A method of forming a lab grown diamond, the method comprising:
using a CVD process to grow a diamond wafer in an environment comprising an N15 isotope;
polishing a surface of the diamond wafer using a dry etching process; and
irradiating and then heating the diamond wafer to form a plurality of nitrogen vacancy centers in the diamond wafer.

15. The method of claim 14 wherein using a CVD process comprises using methane comprising a C12 isotope to grow the diamond wafer.

16. The method of claim 14 wherein polishing comprises polishing the diamond wafer with a plasma process.

17. The method of claim 16 wherein polishing comprises using reactive ion etching.

18. The method of claim 14 wherein the diamond wafer is configured for at least one quantum application.

19. A lab grown diamond produced by the method of claim 14.

20. A diamond wafer comprising:
a diamond structure comprising a C12 isotope and nitrogen; and
an upper surface dry polished with no lattice damage,
the diamond structure configured to form a plurality of nitrogen vacancy centers after application of sufficient heat or irradiation.

21. The diamond wafer of claim 20 wherein the nitrogen comprises a N15 isotope.

22. The diamond wafer of claim 20 wherein the diamond structure comprises a diamond layer on a pure diamond structure.

23. The diamond wafer of claim 20 wherein the diamond structure comprises a unitary wafer with the C12 isotope, the N15 isotope, and the polished upper surface.

24. The diamond wafer of claim 20 further comprising a plurality of nitrogen vacancy centers.

25. A diamond wafer comprising:
a diamond structure comprising a C12 isotope and an N15 isotope; and
an upper surface dry polished with no lattice damage,
the diamond structure configured having a plurality of nitrogen vacancy centers.

26. The diamond wafer of claim 25 wherein the diamond structure comprises a diamond layer on a pure diamond structure.

27. The diamond wafer of claim 25 wherein the diamond structure comprises a unitary wafer with the C12 isotope, the N15 isotope, and the polished upper surface.

28. A method of forming a lab grown diamond, the method comprising:
providing a diamond wafer having a major surface;
polishing the major surface using a dry etching process;
applying a diamond layer to the major surface, the diamond layer comprising a C12 isotope; and
polishing the diamond layer with a mechanical polishing or laser ablation process to form a given diamond wafer.

29. The method of claim 28 wherein applying comprises applying the diamond layer to the major surface in a nitrogen environment.

30. The method of claim 29 where the nitrogen comprises an N15isotope.

31. The method of claim 28 wherein applying comprises applying the diamond layer to the major surface in an environment comprising one or more of nitrogen, tin, nickel, and silicon.
